(19) United States
(12) Patent Application Publication
(10) Pub. No.: US 2022/0115422 A1
(43) Pub. Date: Apr. 14, 2022

(54) IMAGE SENSOR AND METHOD OF FABRICATING THE SAME

(71) Applicant: SAMSUNG ELECTRONICS CO., LTD., SUWON-SI (KR)

(72) Inventors: MINKWAN KIM, Hwaseong-si (KR); IN SUNG JOE, Seoul (KR); Jinhyung KIM, Hwaseong-si (KR); Dhami PARK, Suwon-si (KR); INYONG PARK, Seongnam-si (KR); Kisang YOON, Suwon-si (KR)

(21) Appl. No.: 17/368,039

(22) Filed: Jul. 6, 2021

(30) Foreign Application Priority Data
Oct. 8, 2020 (KR) 10-2020-0130509

(51) Int. Cl. H01L 27/146

(52) U.S. Cl. CPC H01L 27/1463; H01L 27/1462; H01L 27/14636; H01L 27/14627; H01L 27/14612; H01L 27/14621

(57) ABSTRACT

Disclosed is an image sensor including a substrate that includes a plurality of pixel sections and having a first surface and a second surface opposite to each other, an antireflective layer disposed on the second surface of the substrate, a passivation layer disposed on the antireflective layer, a plurality of color filters disposed on the passivation layer and corresponding pixel sections, a plurality of micro-lenses disposed on the color filters, and a gap region that separates the micro-lenses from each other. The gap region extends between the color filters and separates the color filters from each other. The gap region exposes a portion of a top surface of the passivation layer. A thickness of the passivation layer is less than a thickness of the antireflective layer.

### CROSS-REFERENCE TO RELATED APPLICATION

This U.S. nonprovisional application claims priority under 35 U.S.C § 119 to Korean Patent Application No. 10-2020-0130509 filed on Oct. 8, 2020 in the Korean Intellectual Property Office, the disclosure of which is incorporated by reference herein in its entirety.

### TECHNICAL FIELD

The present inventive concepts relate to an image sensor and a method of fabricating the same, and more particularly, to an image sensor with minimized light sensitivity loss and a method of fabricating the same.

### DISCUSSION OF THE RELATED ART

An image sensor is a semiconductor device that transforms light into electrical signals. Recent advances in computer and communication industries have led to increased demand for high performances image sensors in various consumer electronic devices such as digital cameras, camcorders, PCSs (personal communication systems), game devices, security cameras, medical micro cameras, and others.

Typical image sensors include charge coupled device (CCD) type image sensors and complementary metal oxide semiconductor (CMOS) type image sensors. A CMOS type image sensor may be abbreviated to CIS (CMOS image sensor). The CIS has a plurality of two-dimensionally arranged pixels. Each of the pixels includes a photodiode. The photodiode transforms an incident light into an electrical signal. The plurality of pixels are defined by a deep isolation pattern disposed therebetween.

Conventional image sensors may include lenses and color filters disposed on the pixels. In some cases, however, there may be optical interference between pixels, which may cause decreased light sensitivity.

### SUMMARY

Some example embodiments of the present inventive concepts provide an image sensor capable of preventing crosstalk and minimizing sensitivity loss.

According to some example embodiments of the present inventive concepts, an image sensor may include: a substrate that includes a plurality of pixel sections, the substrate having a first surface and a second surface opposite to each other; an antireflective layer disposed on the second surface of the substrate; a passivation layer disposed on the antireflective layer; a plurality of color filters disposed on the passivation layer and corresponding pixel sections; a plurality of micro-lenses disposed on the color filters; and a gap region that separates the micro-lenses from each other. The gap region may extend between the color filters and separate the color filters from each other. The gap region may expose a portion of a top surface of the passivation layer. A thickness of the passivation layer may be less than a thickness of the antireflective layer.

According to some example embodiments of the present inventive concepts, an image sensor may include: a substrate that includes a plurality of pixel sections; an antireflective layer disposed on the substrate; a plurality of grid patterns disposed between the pixel sections and on the antireflective layer; a passivation layer disposed on the antireflective layer, the passivation layer conformally covering top and lateral surfaces of the grid patterns; a plurality of color filters disposed on the passivation layer and corresponding pixel sections; a plurality of micro-lenses disposed on the color filters; and a gap region that separates the micro-lenses from each other. The gap region may extend between the color filters and separate the color filters from each other. The gap region may expose a portion of a top surface of the passivation layer. An uppermost surface of the passivation layer may be disposed at a level higher than a lowermost surface of each of the color filters.

According to some example embodiments of the present inventive concepts, an image sensor may include: a substrate that includes a plurality of pixel sections, the substrate having a first surface and a second surface opposite to each other; a deep isolation pattern disposed between the pixel sections and in the substrate; a transistor disposed on the first surface of the substrate; an antireflective layer disposed on the second surface of the substrate; a passivation layer disposed on the antireflective layer; a plurality of color filters disposed on the passivation layer and corresponding pixel sections; a plurality of micro-lenses disposed on the color filters; and a gap region that separates the micro-lenses from each other. A thickness of the passivation layer may be less than a thickness of the antireflective layer. The gap region may extend between the color filters and separate the color filters from each other. The gap region may expose a portion of a top surface of the passivation layer.

### BRIEF DESCRIPTION OF THE DRAWINGS

The above and other aspects and features of the present disclosure will become more apparent by describing in detail example embodiments thereof with reference to the attached drawings, in which:

FIG. 1 illustrates a simplified block diagram of an image sensor according to some example embodiments of the present inventive concepts.

FIG. 2 illustrates a circuit diagram for an active pixel sensor array of an image sensor according to some example embodiments of the present inventive concepts.

FIG. 3 is a plan view of an image sensor according to some example embodiments of the present inventive concepts.

FIG. 4 is a cross-sectional view taken along line I-I′ of FIG. 3.

FIG. 5 is a plan view of an image sensor according to some example embodiments of the present inventive concepts.

FIG. 6 is a cross-sectional view taken along line I-I′ of FIG. 5.

FIGS. 7 to 14 are cross-sectional views taken along line I-I′ of FIG. 3, showing a method of fabricating an image sensor according to some example embodiments of the present inventive concepts.

FIG. 15 is a cross-sectional view of an image sensor according to some example embodiments of the present inventive concepts.

FIG. 16 is a cross-sectional view of an image sensor according to some example embodiments of the present inventive concepts.

FIG. 17 is a plan view of an image sensor according to some example embodiments of the present inventive concepts.

FIG. 18 is a cross-sectional view taken along line II-II′ of FIG. 16.

### DETAILED DESCRIPTION OF EMBODIMENTS

Hereinafter, various example embodiments will be described in detail with reference to the accompanying drawings. Like reference symbols in the drawings may denote like elements, and to the extent that a description of an element has been omitted, it may be understood that the element is at least similar to corresponding elements that are described elsewhere in the specification. Additionally, description of a singular element may apply to a plurality of the same elements, unless the context of the description or referenced drawings indicates otherwise.

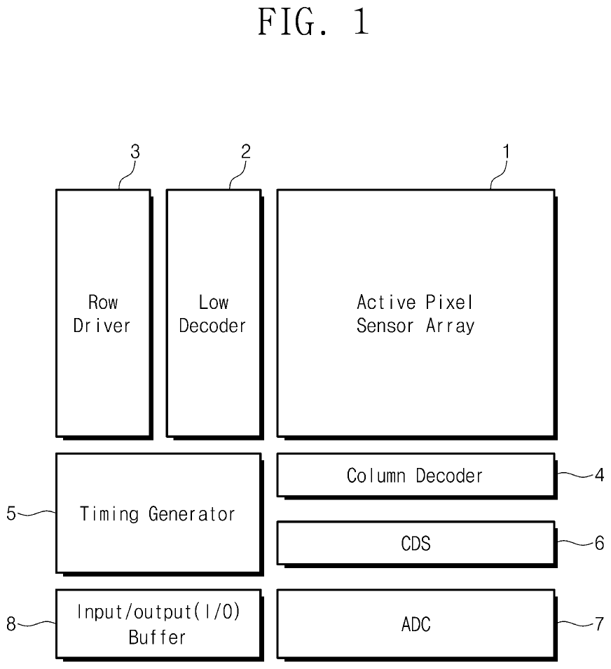

FIG. 1 illustrates a simplified block diagram of an image sensor according to some example embodiments of the present inventive concepts.

Referring to FIG. 1, an image sensor may include an active pixel sensor array 1, a row decoder 2, a row driver 3, a column decoder 4, a timing generator 5, a correlated double sampler (CDS) 6, an analog-to-digital converter (ADC) 7, and an input/output (I/O) buffer 8.

The active pixel sensor array 1 may include a plurality of two-dimensionally arranged pixels. Each pixel may be configured to convert optical signals into electrical signals. The active pixel sensor array 1 may be driven by a plurality of driving signals, such as a pixel select signal, a reset signal, and a charge transfer signal, which are provided from the row driver 3. In addition, the correlated double sampler 6 may be provided with the electrical signals which are converted by the active pixel sensor array 1.

The row driver 3 may provide the active pixel sensor array 1 with several driving signals for driving several pixels in accordance with a decoded result obtained from the row decoder 2. For example, when the plurality of pixels is arranged in a matrix shape, the driving signals may be provided for each row.

The timing generator 5 may provide timing and control signals to the row decoder 2 and the column decoder 4.

The correlated double sampler 6 may receive the electrical signals generated from the active pixel sensor array 1, and may hold and sample the received electrical signals. The correlated double sampler 6 may perform a double sampling operation to sample a specific noise level and a signal level of the electrical signal, and then may output a difference level corresponding to a difference between the noise and signal levels.

The analog-to-digital converter 7 may convert analog signals, which correspond to the difference level received from the correlated double sampler 6, into digital signals and then output the converted digital signals.

The input/output buffer 8 may latch the digital signals and then sequentially output the latched digital signals to an image signal processing unit in response to the decoded result obtained from the column decoder 4.

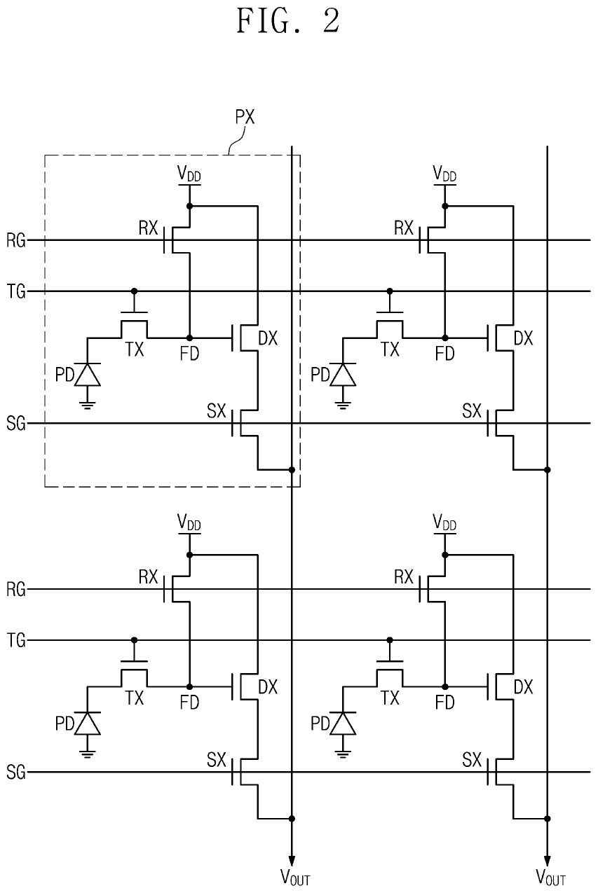

FIG. 2 illustrates a circuit diagram for an active pixel sensor array of an image sensor according to some example embodiments of the present inventive concepts.

Referring to FIGS. 1 and 2, the active pixel sensor array 1 may include a plurality of pixel sections PX, and the pixel sections PX may be arranged in a matrix shape. Each of the pixel sections PX may include a transfer transistor TX and logic transistors RX, SX, and DX. RX, SX, and DX may refer to a reset transistor RX, a selection transistor SX, and a drive transistor DX. The transfer transistor TX, the reset transistor RX, and the selection transistor SX may respectively include a transfer gate TG, a reset gate RG, and a selection gate SG. Each of the pixel sections PX may further include a photoelectric conversion element PD and a floating diffusion region FD.

The photoelectric conversion element PD may create and accumulate photo-charges in response to externally incident light. The photoelectric conversion element PD may be a photodiode including a P-type impurity region and an N-type impurity region. The transfer transistor TX may transfer charges generated in the photoelectric conversion element PD into the floating diffusion region FD. The floating diffusion region FD may accumulate and store the charges generated and transferred from the photoelectric conversion element PD. The drive transistor DX may be controlled by photo-charges accumulated in the floating diffusion region FD.

The reset transistor RX may periodically reset the charges accumulated in the floating diffusion region FD. The reset transistor RX may have a drain electrode connected to the floating diffusion region FD and a source electrode connected to a power voltage V_{DD}. When the reset transistor RX is turned on, the floating diffusion region ED may be supplied with the power voltage V_{DD} connected to the source electrode of the reset transistor RX. Accordingly, when the reset transistor RX is turned on, the charges accumulated in the floating diffusion region FD may be exhausted and thus the floating diffusion region FD may be reset.

The drive transistor DX may serve as a source follower buffer amplifier. The drive transistor DX may amplify a variation in electrical potential of the floating diffusion region FD and may output the amplified electrical potential to an output line V_{OUT}.

The selection transistor SX may select each row of the pixels P to be readout. When the selection transistor SX is turned on, the power voltage V_{DD} may be applied to a drain electrode of the drive transistor DX.

FIG. 2 an example unit pixel section PX that includes one photoelectric conversion element PD and four transistors TX, RX, DX, and SX, but the image sensor according to the present inventive concepts is not necessarily limited thereto. For example, neighboring pixel sections PX may share the reset transistor RX, the drive transistor DX, or the selection transistor SX. Therefore, the image sensor may have increased integration.

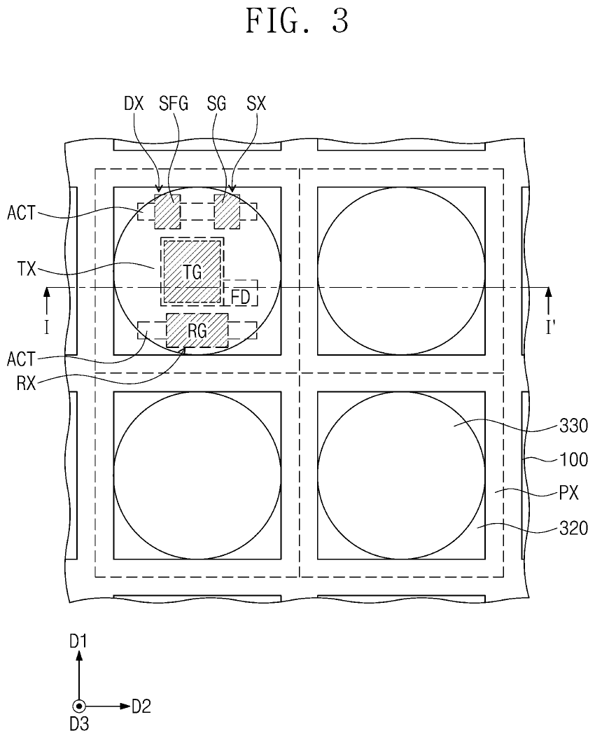

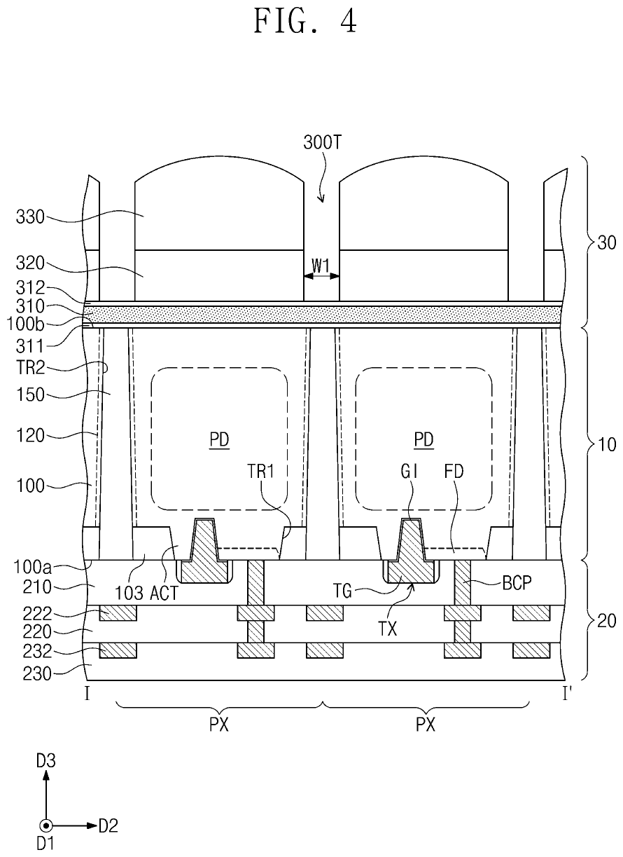

FIG. 3 is a plan view of an image sensor according to some example embodiments of the present inventive concepts. FIG. 4 is a cross-sectional view taken along line I-I′ of FIG. 3. Although FIG. 3 depicts that transfer, drive, selection, and reset gates TG, SFG, SG, and RG are disposed on a single pixel section PX, the present inventive concepts are not limited thereto.

Referring to FIGS. 3 and 4, an image sensor may include a photoelectric conversion layer 10, a wiring layer 20, and an optical transmittance layer 30. The photoelectric conversion layer 10 may be disposed between the wiring layer 20 and the optical transmittance layer 30.

The photoelectric conversion layer 10 may include a substrate 100, and the substrate 100 may include a plurality of pixel sections PX. The substrate 100 may be a semiconductor substrate (e.g., a silicon substrate, a germanium substrate, a silicon-germanium substrate, a II-VI group compound semiconductor substrate, or a III-V group compound semiconductor substrate) or a silicon-on-insulator (SOI) substrate. The substrate 100 may have a first surface 100a and a second surface 100b opposite to each other. The plurality of pixel sections PX may be two-dimensionally arranged along a first direction D1 and a second direction D2 that are parallel to the second surface 100b of the substrate 100. The first direction D1 and the second direction D2 may intersect each other.

The photoelectric conversion layer 10 may further include a deep isolation pattern 150 disposed in the substrate 100 between the plurality of pixel sections PX. When viewed in plan, the deep isolation pattern 150 may have a lattice structure that surrounds each pixel section of the plurality of pixel sections PX. The deep isolation pattern 150 may penetrate at least a portion of the substrate 100 along a third direction D3 perpendicular to the second surface 100b of the substrate 100. According to some example embodiments, the deep isolation pattern 150 may extend from the first surface 100a toward the second surface 100b of the substrate 100, and may have a bottom surface substantially coplanar with the second surface 100b of the substrate 100. The deep isolation pattern 150 may prevent cross-talk issues between neighboring pixel sections PX. The deep isolation pattern 150 may include a dielectric material whose refractive index is less than that of the substrate 100. The deep isolation pattern 150 may include a single dielectric layer or a plurality of dielectric layers. For example, the deep isolation pattern 150 may include a silicon oxide layer, a silicon oxynitride layer, and/or a silicon nitride layer.

Each of the plurality of pixel sections PX may include a photoelectric conversion region PD and a doped region 120 that extends along a lateral surface of the deep isolation pattern 150. In the description below, the photoelectric conversion region PD may indicate an area on which is disposed the photoelectric conversion element PD of FIGS. 1 and 2. The doped region 120 may be disposed between the photoelectric conversion region PD and the deep isolation pattern 150.

The substrate 100 may include a first conductivity type, and the photoelectric conversion region PD may be an area doped with impurities having a second conductivity type different from the first conductivity type. For example, the first conductivity type and the second conductivity type may be a P-type and an N-type, respectively. For example, the impurities having the second conductivity type may include N-type impurities, such as one or more of phosphorus, arsenic, bismuth, and antimony. The photoelectric conversion region PD and the substrate 100 may form a PN junction to constitute a photodiode. The doped region 120 may be doped with impurities having the first conductivity type. The doped region 120 may prevent the photoelectric conversion region PD from receiving electrons that have been trapped in dangling bonds possibly present on a lateral surface of each of the plurality of pixel sections PX, and thus the image senor may avoid dark currents or white spots. The impurities having the first conductivity type may include P-type impurities, such as boron.

A shallow isolation pattern 103 may be disposed adjacent to the first surface 100a of the substrate 100. Each of the plurality of pixel sections PX may include active regions ACT defined by the shallow isolation pattern 103. The shallow isolation pattern 103 may include one or more of a silicon oxide layer, a silicon nitride layer, and a silicon oxynitride layer. The deep isolation pattern 150 may penetrate the shallow isolation pattern 103, thereby extending into the substrate 100. The shallow isolation pattern 103 may be disposed in a first trench TR1 that extends into the substrate 100 from the first surface 100a of the substrate 100. The deep isolation pattern 150 may be disposed in a second trench TR2 that penetrates the shallow isolation pattern 103 and extends toward the second surface 100b of the substrate 100. Each of the first and second trenches TR1 and TR2 may have a width in a direction (e.g., the second direction D2) parallel to the second surface 100b of the substrate 100. The first trench TR1 may have a bottom surface whose width is greater than that of an upper portion of the second trench TR2.

Transfer transistors TX and logic transistors RX, SX, and DX may be disposed on the first surface 100a of the substrate 100. Each of the transistors TX, RX, SX, and DX may be disposed on the active region ACT that corresponds to the pixel section PX. The transfer transistor TX may include a transfer gate TG and a floating diffusion region FD on the corresponding active region ACT. A lower portion of the transfer gate TG may be inserted into the substrate 100, and an upper portion of the transfer gate TG may protrude upwardly from the first surface 100a of the substrate 100. A gate dielectric layer GI may be interposed between the transfer gate TG and the substrate 100. The floating diffusion region FD may be disposed on a corresponding active region ACT on one side of the transfer gate TG. The floating diffusion region FD may be an area doped with impurities (e.g., N-type impurities) having the second conductivity type different from the first conductivity type.

Referring to FIG. 3, the drive transistor DX may include a drive gate SFG on a corresponding active region ACT, and the selection transistor SX may include a selection gate SG on a corresponding active region ACT. The reset transistor RX may include a reset gate RG on a corresponding active region ACT. An additional gate dielectric layer GI may be interposed between the substrate 100 and each of the drive, selection, and reset gates SFG, SG, and RG.

Referring to FIG. 4, the wiring layer 20 may be disposed on the first surface 100a of the substrate 100. The wiring layer 20 may include a first interlayer dielectric layer 210, a second interlayer dielectric layer 220, and a third interlayer dielectric layer 230 that are sequentially stacked on the first surface 100a of the substrate 100. The wiring layer 20 may further include contact plugs BCP in the first interlayer dielectric layer 210, first wiring patterns 222 in the second interlayer dielectric layer 220, and second wiring patterns 232 in the third interlayer dielectric layer 230. The first interlayer dielectric layer 210 may be disposed on the first surface 100a of the substrate 100 and may at least partially cover the transistors TX, RX, SX, and DX, and the contact plugs BCP may be connected to terminals of the transistors TX, RX, SX, and DX. The contact plugs BCP may be connected to corresponding first wiring patterns 222, and the first wiring patterns 222 may be connected to corresponding second wiring patterns 232. The first and second wiring patterns 222 and 232 may be electrically connected through the contact plugs BCP to the transistors TX, RX, SX, and DX. Each of the first, second, and third interlayer dielectric layers 210, 220, and 230 may include a dielectric material, and the contact plugs BCP, the first wiring patterns 222, and the second wiring patterns 232 may include a conductive material.

The optical transmittance layer 30 may be disposed on the second surface 100b of the substrate 100. The optical transmittance layer 30 may include a dielectric layer 311, an antireflective layer 310, a passivation layer 312, a plurality of color filters 320, a plurality of micro-lenses 330, and a gap region 300T. The optical transmittance layer 30 may focus and filter incident light, and the photoelectric conversion layer 10 may be provided with the focused and filtered light.

The dielectric layer 311 may be disposed on the second surface 100b of the substrate 100. The dielectric layer 311 may conformally cover the second surface 100b of the substrate 100. The dielectric layer 311 may have a thickness less than that of the antireflective layer 310. The thickness of the dielectric layer 311 may be substantially uniform along the second direction D2 parallel to the second surface 100b of the substrate 100. In this description, the term “thickness” may mean a vertical distance measured in the third direction D3 perpendicular to the second surface 100b of the substrate 100. The dielectric layer 311 may include one or more of metal oxide and nitride. For example, the metal oxide may include aluminum oxide, and the nitride may include silicon nitride.

The antireflective layer 310 may be disposed on the dielectric layer 311. The antireflective layer 310 may conformally cover a top surface of the dielectric layer 311. The antireflective layer 310 may be substantially uniform along the second direction D2. The antireflective layer 310 may prevent light reflection such that the photoelectric conversion region PD may be allowed to readily receive light incident onto the second surface 100b of the substrate 100. The antireflective layer 310 may include, for example, a silicon oxide layer, a silicon nitride layer, a silicon oxynitride layer, or a high-k dielectric layer (e.g., a hafnium oxide layer or an aluminum oxide layer).

The passivation layer 312 may be disposed on the antireflective layer 310. The passivation layer 312 may conformally cover a top surface of the antireflective layer 310. The passivation layer 312 may have a thickness less than that of the antireflective layer 310. The passivation layer 312 may be substantially flat along the second direction D2. The passivation layer 312 may include one or more of metal oxide and nitride. For example, the metal oxide may include aluminum oxide, and the nitride may include silicon nitride.

The plurality of color filters 320 may be disposed on the passivation layer 312. Each of the plurality of color filters 320 may be disposed to vertically (or, in the third direction D3) overlap the photoelectric conversion region PD on the pixel section PX that corresponds thereto. In an example embodiment, based on a unit pixel, the color filter 320 may include one of red, green, and blue filters. The color filters 320 may be arranged two-dimensionally. In one example embodiment, the color filters 320 may include a yellow filter, a magenta filter, and a cyan filter.

The micro-lenses 330 may be disposed on the plurality of color filters 320. The micro-lenses 330 may be disposed to vertically (or, in the third direction D3) overlap the photoelectric conversion region PD of the pixel section PX that corresponds thereto. Each of the micro-lenses 330 may have a convex shape to condense light that is incident on the pixel section PX.

The gap region 300T may be formed on the passivation layer 312. The gap region 300T may be disposed to vertically (or, in the third direction D3) overlap the deep isolation pattern 150. The gap region 300T may separate the micro-lenses 330 from each other. The gap region 300T may extend between the color filters 320 and may separate the color filters 320 from each other. The gap region 300T may partially expose a top surface of the passivation layer 312. The gap region 300T may expose sidewalls of the color filters 320 and sidewalls of the micro-lenses 330. The gap region 300T may have a width W1 that is about 15% to about 25% of a width of the pixel section PX. For example, the width W1 of the gap region 300T may range from about 40 nm to about 350 nm. In this description of the example embodiment illustrated in FIG. 4, the term “width” may mean a distance measured in the second direction D2 parallel to the second surface 100b of the substrate 100. In some embodiments, the gap region 300T may have a tapered width, wherein the width W1 of the gap region 300T decreases near a top portion thereof. In other example embodiments, the width W1 of the gap region 300T may increase near a top portion thereof. In some example embodiments, the width W1 of the gap region 300T may change according to the widths of the color filters 320 and the micro-lenses 330. A plurality of gap regions 300T may have a lattice shape when viewed in plan.

According to the present inventive concepts, the gap region 300T may be included such that the color filters 320 may be spaced apart from each other, and that the micro-lenses 330 may be separated from each other, which may achieve optical isolation. Therefore, the pixel section PX may receive light incident on the micro-lens 330 that corresponds to the pixel section PX, and the light may be prevented from entering other pixel sections PX. Accordingly, optical interference may be prevented between the pixel sections PX. According to some example embodiments of the present inventive concepts, even when no grid pattern is present, crosstalk issues may be prevented, loss of light sensitivity may be minimized, and a signal-to-noise ratio (SNR) may be increased.

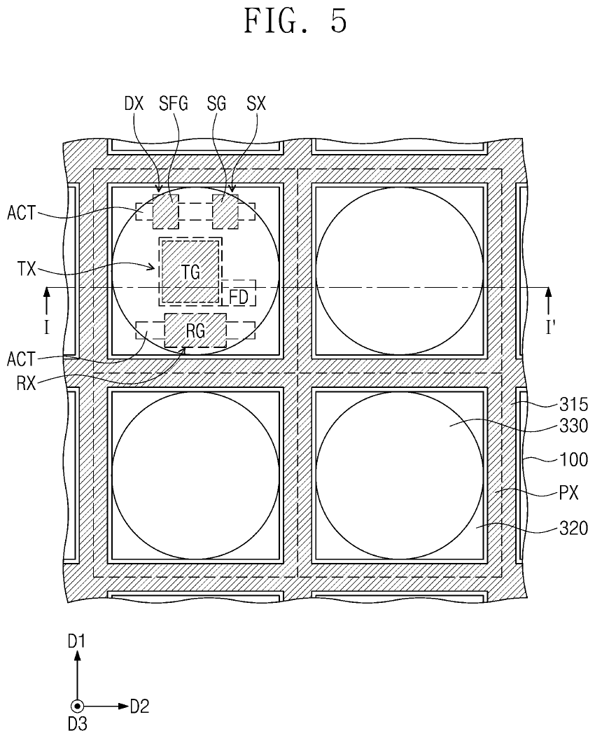

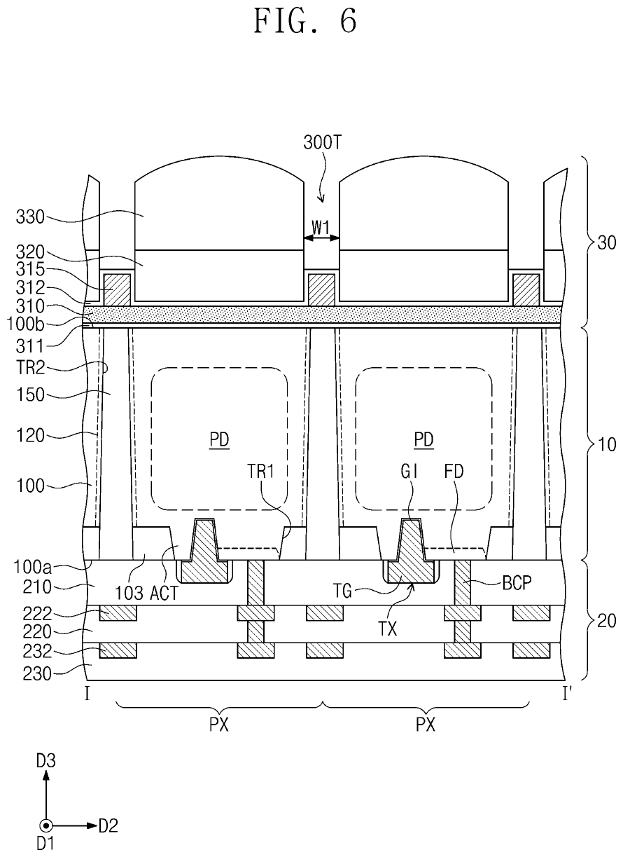

FIG. 5 is a plan view showing an image sensor according to some example embodiments of the present inventive concepts. FIG. 6 is a cross-sectional view taken along line I-I′ of FIG. 5. To minimize duplicate description, the following discussion will focus on differences from the image sensor discussed with reference to FIGS. 1 to 4. Although FIG. 5 depicts that transfer, drive, selection, and reset gates TG, SFG, SG, and RG are disposed on a single pixel section PX, the present inventive concepts are not limited thereto.

Referring to FIGS. 5 and 6, an image sensor may include the photoelectric conversion layer 10, the wiring layer 20, and the optical transmittance layer 30. The optical transmittance layer 30 may include the dielectric layer 311, the antireflective layer 310, the passivation layer 312, the plurality of color filters 320, the plurality of micro-lenses 330, and the gap region 300T, and may further include a grid pattern 315.

The grid pattern 315 may be provided between the pixel sections PX and disposed on the antireflective layer 310. The grid pattern 315 may be interposed between the antireflective layer 310 and the passivation layer 312. For example, the grid pattern 315 may vertically overlap the deep isolation pattern 150. The present inventive concepts, however, are not necessarily limited thereto, and the grid pattern 315 may not vertically overlap the deep isolation pattern 150. A bottom surface of the grid pattern 315 may be disposed at a lower level than a bottom surface of each of the color filters 320. The passivation layer 312 may conformally cover top and lateral surfaces of each of a plurality of grid patterns 315. The passivation layer 312 may be interposed between a sidewall of the color filter 320 and a sidewall of the grid pattern 315. When viewed in plan, the grid pattern 315 may have a lattice shape.

When the substrate 100 receives light on the second surface 100b thereof, the grid pattern 315 may guide the light to enter the photoelectric conversion region PD. The grid pattern 315 may include a metallic material or a low-refractive-index (LRI) material. The metallic material may include, for example, tungsten (W) or titanium (Ti). The low-refractive-index (LRI) material may include, for example, silicon oxide or a material whose refractive index is less than those of the color filters 320.

Except for the explanation of the grid pattern 315, the image sensor if FIGS. 5 and 6 may be substantially the same as the image sensor discussed above with reference to FIGS. 1 to 4.

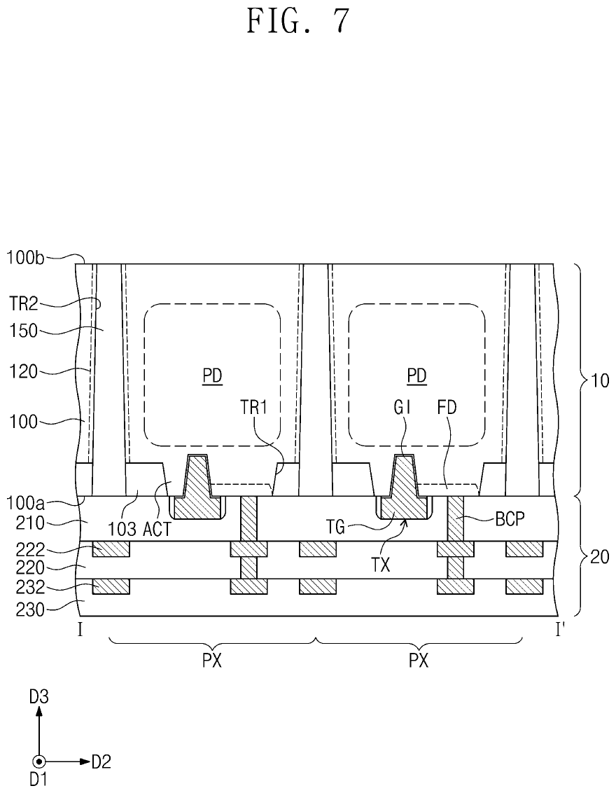

FIGS. 7 to 11 are cross-sectional views taken along line I-I′ of FIG. 3, showing a method of fabricating an image sensor according to some example embodiments of the present inventive concepts. To minimize duplicate description, omissions will be made of explanations about the image sensor discussed with reference to FIGS. 1 to 4, and the method of fabricating the image sensor will be mainly described.

Referring to FIGS. 3 and 7, a substrate 100 may be provided which has a first surface 100a and a second surface 100b opposite to each other. A first trench TR1 may be formed adjacent to the first surface 100a of the substrate 100. The first trench TR1 may define active regions ACT in the substrate 100. The first trench TR1 may be filled to form a shallow isolation pattern 103. A second trench TR2 may be formed in the substrate 100. The second trench TR2 may define a plurality of pixel sections PX in the substrate 100. The second trench TR2 may be filled to form a deep isolation pattern 150. A doped region 120 may be formed in the substrate 100 exposed to the second trench TR2. The formation of the doped region 120 may include, for example, doping impurities (e.g., P-type impurities) of a first conductivity type into the substrate 100 exposed to the second trench TR2. A photoelectric conversion region PD may be formed on each of the plurality of pixel sections PX. The formation of the photoelectric conversion region PD may include, for example, doping the substrate 100 with impurities of a second conductivity type (e.g., N-type) different from the first conductivity type (e.g., P-type). Transistors TX, RX, SX, and DX may be formed on the first surface 100a of the substrate 100 and on each pixel section PX. The processes mentioned above may form a photoelectric conversion layer 10.

A wiring layer 20 may be formed on the first surface 100a of the substrate 100. For example, a first interlayer dielectric layer 210 may be formed on the first surface 100a of the substrate 100, and may at least partially cover the transistors TX, RX, SX, and DX. Contact plugs BCP may be formed in the first interlayer dielectric layer 210, and may be connected to terminals of the transistors TX, RX, SX, and DX. A second interlayer dielectric layer 220 and a third interlayer dielectric layer 230 may be sequentially formed on the first interlayer dielectric layer 210. First wiring patterns 222 and second wiring patterns 232 may be formed in the second interlayer dielectric layer 220 and the third interlayer dielectric layer 230, respectively. The first and second wiring patterns 222 and 232 may be electrically connected through the contact plugs BCP to the transistors TX, RX, SX, and DX.

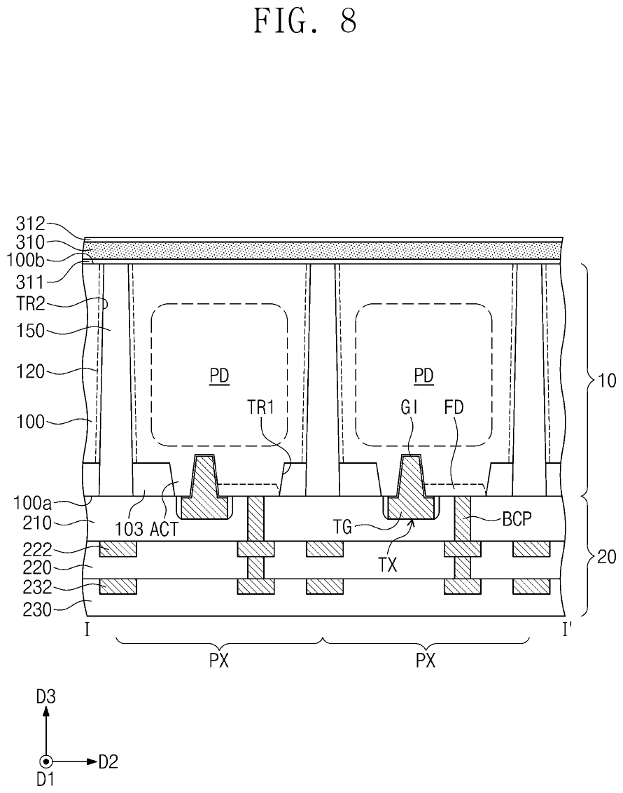

Referring to FIGS. 3 and 8, an optical transmittance layer 30 may be formed on the second surface 100b of the substrate 100. For example, a dielectric layer 311, an antireflective layer 310, and a passivation layer 312 may be sequentially formed on the second surface 100b of the substrate 100. The dielectric layer 311 may conformally cover the second surface 100b of the substrate 100. The dielectric layer 311 may have a thickness that is substantially uniform along the second direction D2. The antireflective layer 310 may conformally cover a top surface of the dielectric layer 311. The antireflective layer 310 may be substantially uniform along the second direction D2. The passivation layer 312 may conformally cover a top surface of the antireflective layer 310. The passivation layer 312 may have a thickness that is substantially flat along the second direction D2.

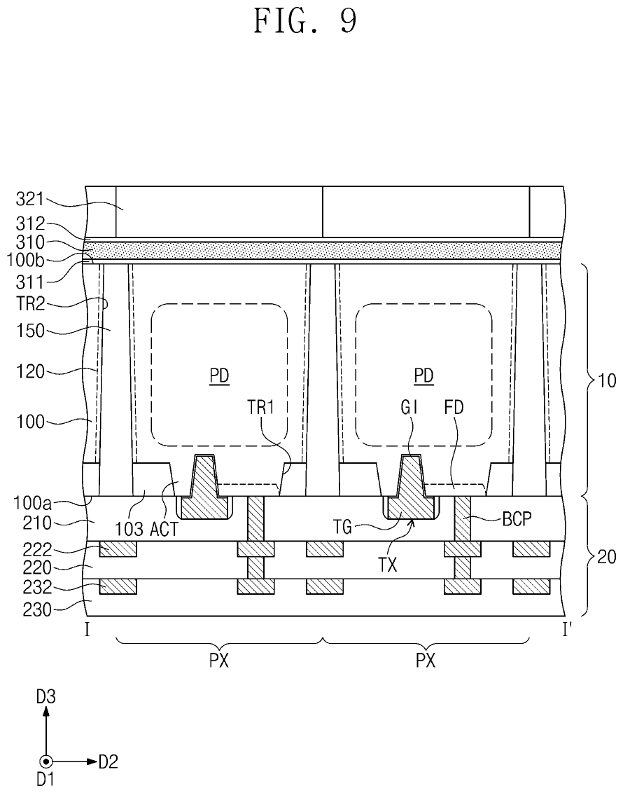

Referring to FIGS. 3 and 9, color filter patterns 321 may be formed on the passivation layer 312. The formation of the color filter patterns 321 may include forming a color filter layer and patterning the color filter layer. The color filter layer may be formed by, for example, a spin coating process. The color filter layer may be patterned by exposure, development, and etching processes. Each of the color filter patterns 321 may vertically (or, in the third direction D3) overlap the photoelectric conversion region PD on the pixel section PX that corresponds thereto.

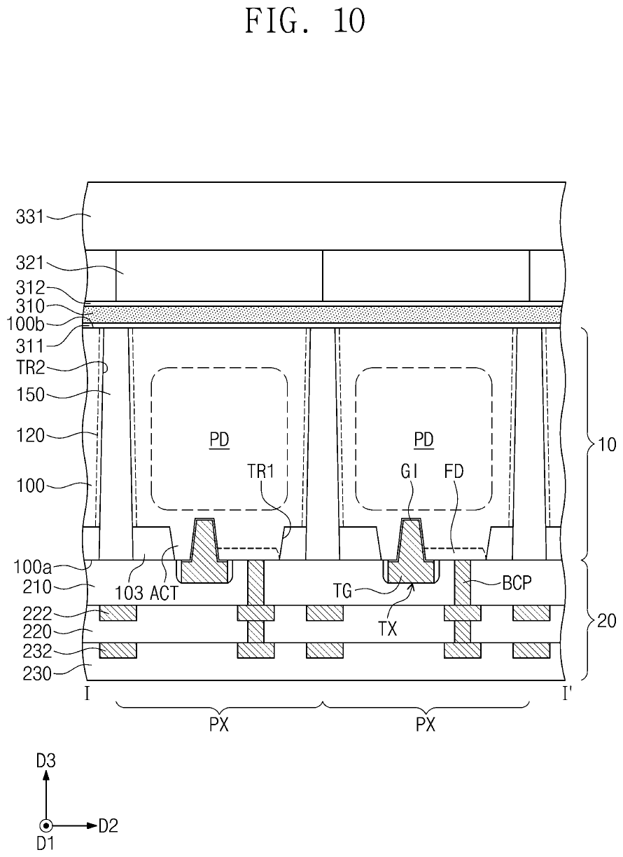

Referring to FIGS. 3 and 10, a first preliminary lens layer 331 may be formed on and cover the color filter patterns 321. The first preliminary lens layer 331 may be formed by a spin coating process that uses a transparent photoresist material or a transparent thermosetting resin.

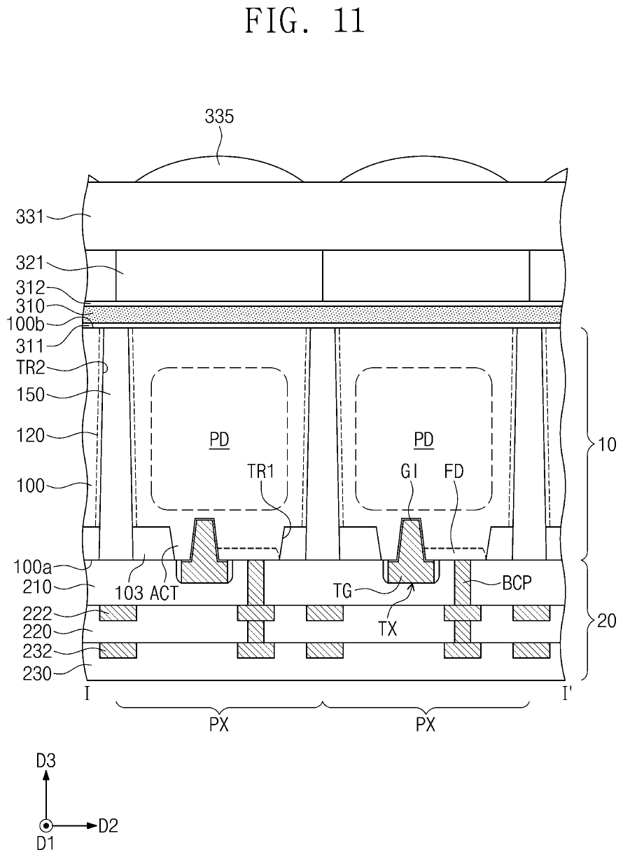

Referring to FIGS. 3 and 11, preliminary lens patterns 335 may be formed on the first preliminary lens layer 331. Each of the preliminary lens patterns 335 may vertically (or, in the third direction D3) overlap the photoelectric conversion region PD of the pixel section PX that corresponds thereto. The formation of the preliminary lens patterns 335 may include performing a photolithography process to form photoresist patterns and performing a reflow process on the photoresist patterns. The reflow process may increase a density of the preliminary lens patterns 335, which may result in an increased chemical resistance. Each of the preliminary lens patterns 335 may have a hemispheric shape.

Referring back to FIGS. 3 and 4, the first preliminary lens layer 331 and the preliminary lens patterns 335 may undergo an etching process (e.g., etch-back process) to form a plurality of color filters 320, a plurality of micro-lenses 330, and a gap region 3001′. For example, the etching process may allow the preliminary lens patterns 335 to transfer their shapes onto the first preliminary lens layer 331. Therefore, the micro-lenses 330 may have, at their upper portions, shapes such as convex hemispheric shapes that correspond to those of the preliminary lens patterns 335. At the same time, in the etching process, the gap region 300T may vertically (or, in the third direction D3) overlap the deep isolation pattern 150. The formation of the gap region 300T may include using the passivation layer 312 as an etch stop layer to etch the first preliminary lens layer 331 and the color filter patterns 321. The formation of the gap region 300T may expose a portion of a top surface of the passivation layer 312, sidewalls of the color filters 320, and sidewalls of the micro-lenses 330. The plurality of color filters 320 may be spaced apart from each other by the gap region 300T, and likewise the plurality of micro-lenses 330 may be spaced apart from each other by the gap region 300T.

According to the present inventive concepts, without additional processes and at the same time when the micro-lenses 330 are formed, the color filters 320 may be spaced apart from each other, and likewise the micro-lenses 330 may be spaced apart from each other, which may achieve optical isolation. Therefore, an image sensor may be fabricated by using fewer processes, with the image sensor being capable of preventing crosstalk issues and increasing light sensitivity.

Referring back to FIGS. 3 and 8, differently from that shown, a grid pattern 315 may further be included after the formation of the antireflective layer 310. For example, the grid pattern 315 may lie on the antireflective layer 310 and to vertically overlap the deep isolation pattern 150. The formation of the grid pattern 315 may include, for example, depositing a metal layer on the antireflective layer 310 and patterning the metal layer. A passivation layer 312 may lie on the antireflective layer 310 and to conformally cover lateral and top surfaces of the grid pattern 315.

Afterwards, processes substantially the same as those discussed with reference to FIGS. 4 and 9 to II may be performed to fabricate the image sensor discussed with reference to FIGS. 5 and 6.

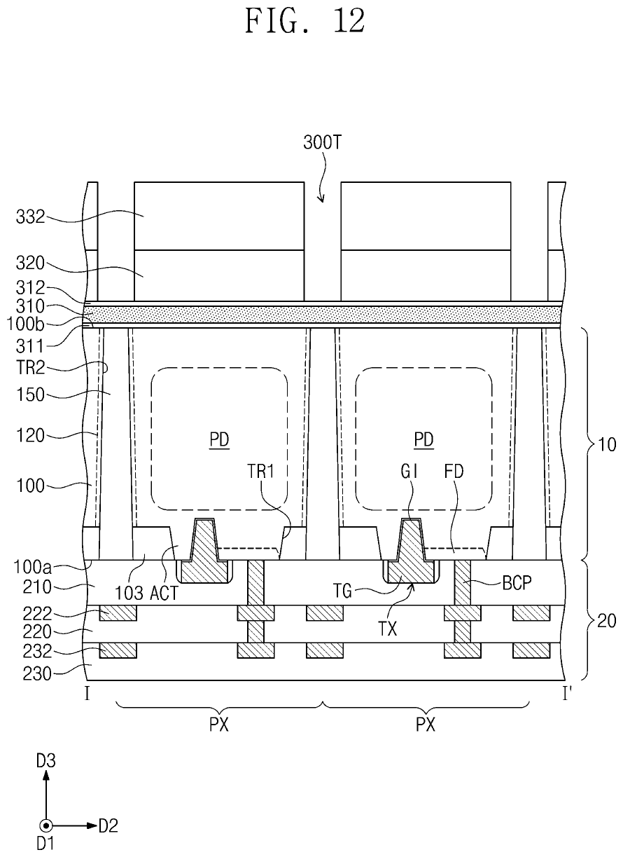

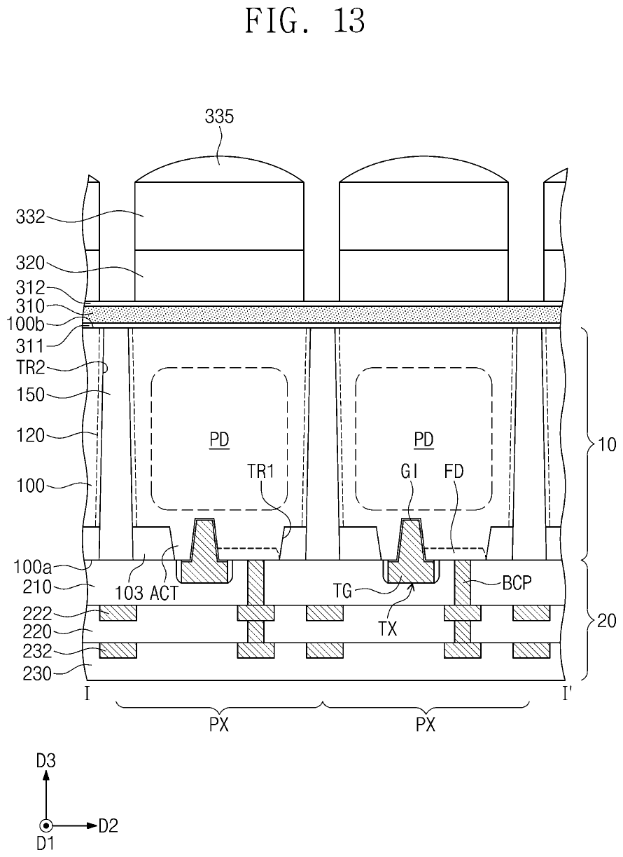

FIGS. 12 and 13 illustrate cross-sectional views taken along line I-I′ of FIG. 3, showing a method of fabricating an image sensor according to some example embodiments of the present inventive concepts. For brevity of description, omission will be made to avoid repetitive explanations about the image sensor discussed with reference to FIGS. 1 to 4.

Referring to FIGS. 7 to 10 and 12, a first preliminary lens layer 331 may be formed on the color filter patterns 321. The following will omit repetitive explanations discussed with reference to FIGS. 7 to 10. The first preliminary lens layer 331 and the color filter patterns 321 may undergo an etching process to form color filters 320, lens patterns 332, and a gap region 300T. For example, the formation of the gap region 300T may include using the passivation layer 312 as an etch stop layer to etch the first preliminary lens layer 331 and the color filter patterns 321. The formation of the gap region 300T may expose a portion of a top surface of the passivation layer 312, sidewalls of the color filters 320, and sidewalls of the lens patterns 332. The plurality of color filters 320 may be spaced apart from each other by the gap region 300T, and likewise the plurality of lens patterns 332 may be spaced apart from each other by the gap region 300T.

Referring to FIGS. 3 and 13, preliminary lens patterns 335 may be formed on corresponding lens patterns 332. Each of the preliminary lens patterns 335 may vertically (or, in the third direction D3) overlap the photoelectric conversion region PD of the pixel section PX that corresponds thereto. The formation of the preliminary lens patterns 335 may include performing a photolithography process to form photoresist patterns and performing a reflow process on the photoresist patterns. The reflow process may increase a density of the preliminary lens patterns 335, which may result in an increased chemical resistance. Each of the preliminary lens patterns 335 may have a hemispheric shape.

Referring back to FIGS. 3 and 4, the lens pattern 332 and the preliminary lens patterns 335 may undergo an additional etching process (e.g., etch-back process) to form a plurality of micro-lenses 330. For example, the additional etching process may allow the preliminary lens patterns 335 to transfer their shapes onto the lens patterns 332. Therefore, the micro-lenses 330 may have, at their upper portions, shapes such as convex hemispheric shapes that correspond to those of the preliminary lens patterns 335.

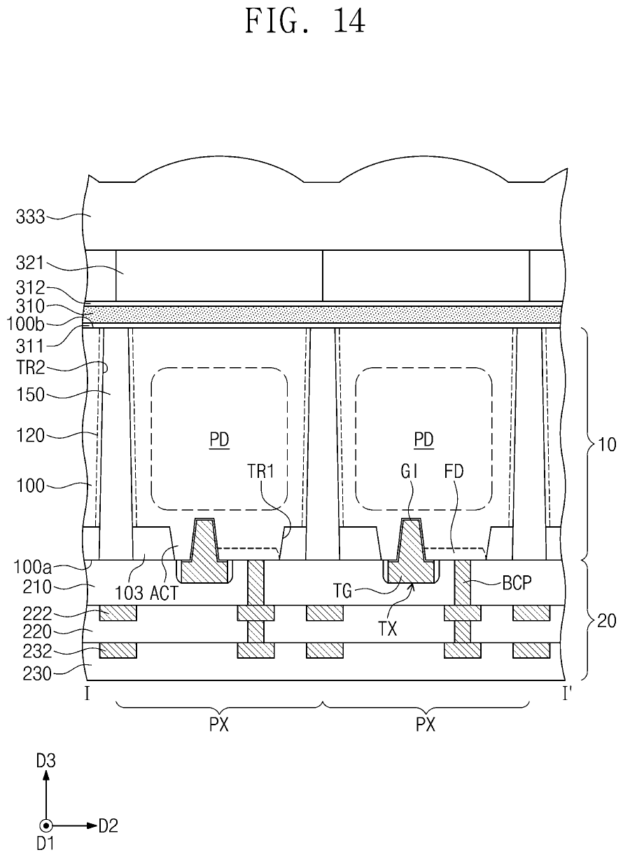

FIG. 14 is a cross-sectional view taken along line I-I′ of FIG. 3, showing a method of fabricating an image sensor according to some example embodiments of the present inventive concepts. For brevity of description, repeated description about the image sensor discussed with reference to FIGS. 1 to 4 will be omitted.

Referring to FIGS. 7 to 11 and 14, preliminary lens patterns 335 may be formed on the first preliminary lens layer 331. The following will omit repetitive explanations discussed with reference to FIGS. 7 to 11. The first preliminary lens layer 331 and the preliminary lens patterns 335 may undergo an etching process (e.g., etch-back process) to form a second preliminary lens layer 333. For example, the etching process may allow the preliminary lens patterns 335 to transfer their shapes onto the first preliminary lens layer 331. Therefore, the second preliminary lens layer 333 may have, at its upper portion, shapes such as convex hemispheric shapes that correspond to those of the preliminary lens patterns 335.

Referring back to FIGS. 3 and 4, the second preliminary lens layer 333 and the color filter patterns 321 may undergo an additional etching process to form color filters 320, micro-lenses 330, and a gap region 300T. For example, the formation of the gap region 300T may include using the passivation layer 312 as an etch stop layer to etch the second preliminary lens layer 333 and the color filter patterns 321. The formation of the gap region 300T may expose a portion of a top surface of the passivation layer 312, sidewalls of the color filters 320, and sidewalls of the micro-lenses 330. The plurality of color filters 320 may be spaced apart from each other by the gap region 300T, and likewise the plurality of micro-lenses 330 may be spaced apart from each other by the gap region 300T.

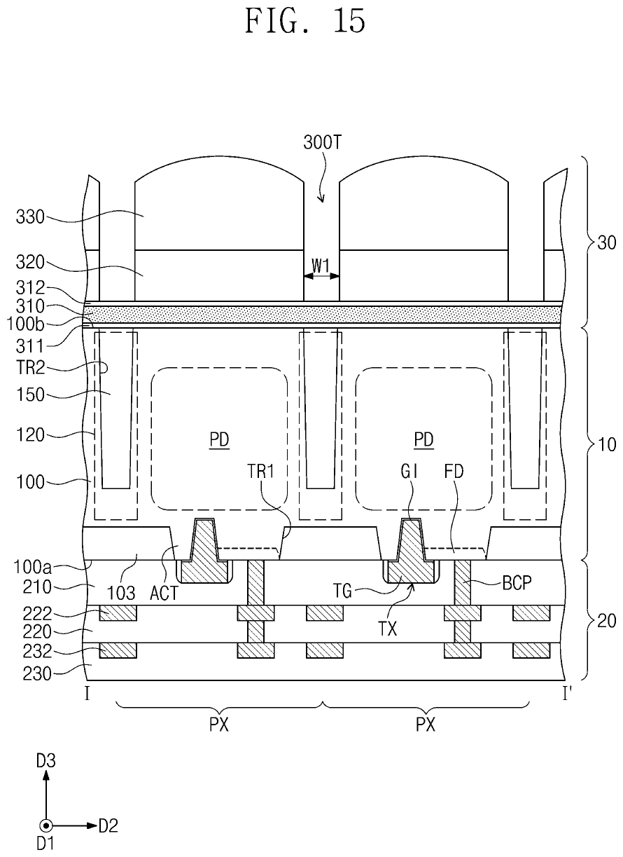

FIG. 15 is a cross-sectional view showing an image sensor according to some example embodiments of the present inventive concepts. For brevity of description, the following discussion will focus on differences from the image sensor discussed with reference to FIGS. 1 to 4.

Referring to FIG. 15, the photoelectric conversion layer 10 may include a substrate 100 including a plurality of pixel sections PX, and may also include a deep isolation pattern 150 disposed in the substrate 100 between the plurality of pixel sections PX. According to some example embodiments, the deep isolation pattern 150 may extend from the second surface 100b toward the first surface 100a of the substrate 100. The bottom surface of the deep isolation pattern 150 may be disposed at a higher level than the first surface 100a of the substrate 100. In this description, the term “level” may mean a height from the second surface 100b of the substrate 100.

Each of the plurality of pixel sections PX may include a photoelectric conversion region PD and a doped region 120 that extends along a lateral surface of the deep isolation pattern 150. The doped region 120 may be disposed between the photoelectric conversion region PD and the deep isolation pattern 150. According to some example embodiments, the doped region 120 may extend along the bottom surface of the deep isolation pattern 150. A shallow isolation pattern 103 may be disposed adjacent to the first surface 100a of the substrate 100. According to some example embodiments, the bottom surface of the deep isolation pattern 150 may be spaced apart from the shallow isolation pattern 103.

Except for the description of the photoelectric conversion layer 10, description of the wiring layer 20 and the optical transmittance layer 30 may be applied to the same components in the image sensor discussed above with reference to FIGS. 1 to 4

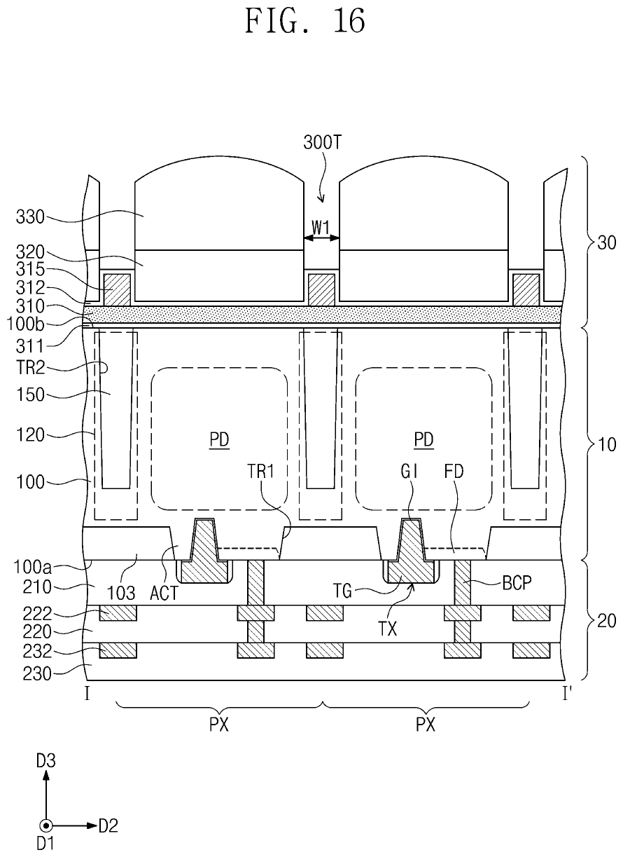

FIG. 16 is a cross-sectional view of an image sensor according to some example embodiments of the present inventive concepts. For brevity of description, the following discussion will focus on differences from the image sensor discussed with reference to FIGS. 1, 2, 5, and 6.

Referring to FIG. 16, the photoelectric conversion layer 10 may include a substrate 100 including a plurality of pixel sections PX, and may also include a deep isolation pattern 150 disposed in the substrate 100 between the plurality of pixel sections PX. According to some example embodiments, the deep isolation pattern 150 may extend from the second surface 100b toward the first surface 100a of the substrate 100. The bottom surface of the deep isolation pattern 150 may be disposed at a higher level than the first surface 100a of the substrate 100.

Each of the plurality of pixel sections PX may include a photoelectric conversion region PD and a doped region 120 that extends along a lateral surface of the deep isolation pattern 150. The doped region 120 may be disposed between the photoelectric conversion region PD and the deep isolation pattern 150. According to some example embodiments, the doped region 120 may extend along the bottom surface of the deep isolation pattern 150. A shallow isolation pattern 103 may be disposed adjacent to the first surface 100a of the substrate 100. According to some example embodiments, the bottom surface of the deep isolation pattern 150 may be spaced apart from the shallow isolation pattern 103.

Except for the description of the photoelectric conversion layer 10, description of the wiring layer 20 and the optical transmittance layer 30 may be applied to like components in the image sensor discussed above with reference to FIGS. 1, 2, 5, and 6.

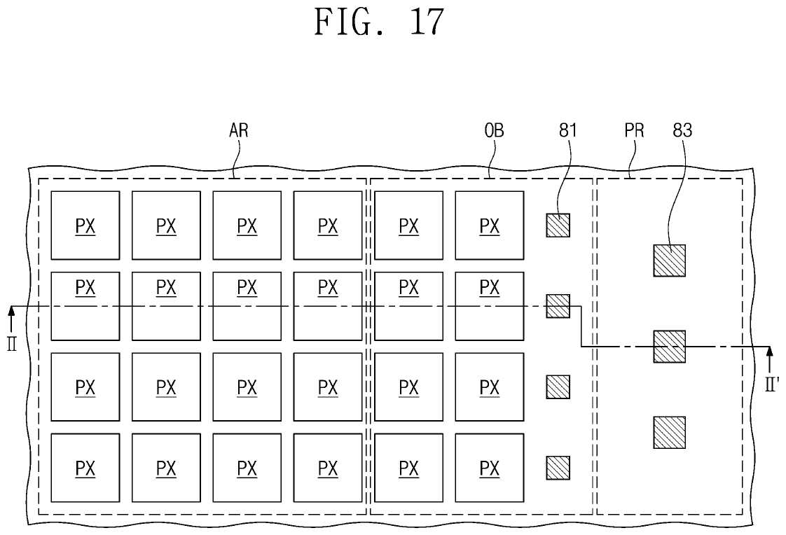

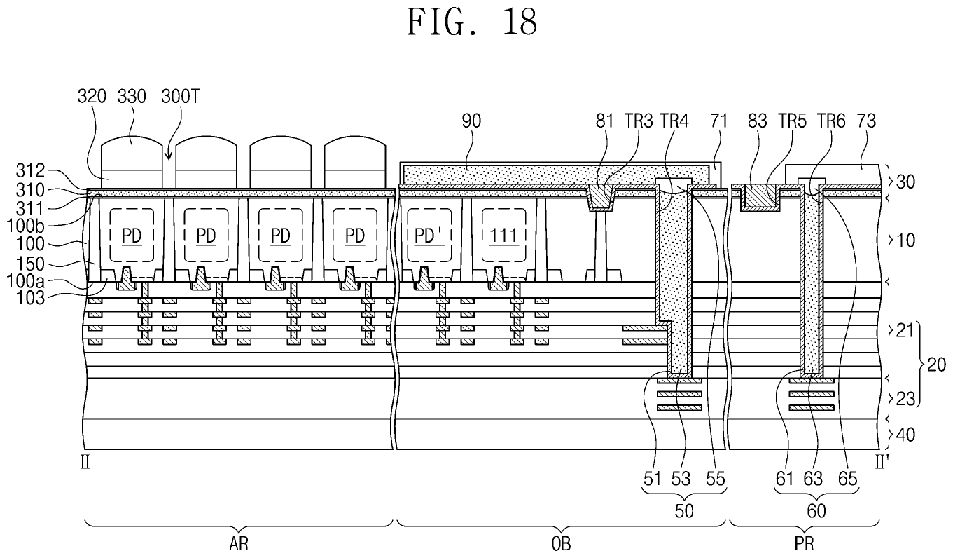

FIG. 17 is a plan view of an image sensor according to some example embodiments of the present inventive concepts. FIG. 18 illustrates a cross-sectional view taken along line 11-11′ of FIG. 17.

Referring to FIGS. 17 and 18, an image sensor may include a substrate 100 including a pixel array area AR, an optical black area OB, and a pad area PR, a wiring layer 20 on a first surface 100a of the substrate 100, a base substrate 40 on the wiring layer 20, and an optical transmittance layer 30 on a second surface 100b of the substrate 100. The wiring layer 20 may be disposed between the base substrate 40 and the first surface 100a of the substrate 100. The wiring layer 20 may include an upper wiring layer 21 adjacent to the first surface 100a of the substrate 100, and may also include a lower wiring layer 23 between the upper wiring layer 21 and the base substrate 40. The pixel array area AR may include a plurality of pixel sections PX and a deep isolation pattern 150 between the plurality of pixel sections PX. The pixel array area AR may be substantially the same as that included in one of the image sensors discussed with reference to FIGS. 1 to 4, 6, 16, and 17. Additionally or alternatively, the deep isolation pattern 150 may be substantially the same as the deep isolation pattern 150 discussed with reference to FIG. 1 to 4, 6, 16, or 17.

A first connection structure 50, a first contact 81, and a bulk color filter 90 may be disposed on the optical black area OB of the substrate 100. The first connection structure 50 may include a first light-shield pattern 51, a first separation pattern 53, and a first capping pattern 55. The first light-shield pattern 51 may be disposed on the second surface 100b of the substrate 100. The first light-shield pattern 51 may cover the passivation layer 312, and may conformally cover an inner wall of one of third and fourth trenches TR3 and TR4. The first light-shield pattern 51 may penetrate the photoelectric conversion layer 10 and the upper wiring layer 21. The first light-shield pattern 51 may be connected to the deep isolation pattern 150 of the photoelectric conversion layer 10, and may be connected to wiring lines in the upper and lower wiring layers 21 and 23. Therefore, the first connection structure 50 may electrically connect the photoelectric conversion layer 10 to the wiring layer 20. The first light-shield pattern 51 may include a metallic material (e.g., tungsten). The first light-shield pattern 51 may block light incident onto the optical black area OB.

The first contact 81 may fill a remaining portion the third trench TR3. The first contact 81 may include a metallic material (e.g., aluminum). The first contact 81 may be connected to the deep isolation pattern 150. The first separation pattern 53 may fill a remaining portion of the fourth trench TR4. The first separation pattern 53 may penetrate the photoelectric conversion layer 10 and a portion of the wiring layer 20. The first separation pattern 53 may include a dielectric material. The first capping pattern 55 may be disposed on the first separation pattern 53.

The bulk color filter 90 may be disposed on the first connection structure 50 and the first contact 81. The bulk color filter 90 may cover the first connection structure 50 and the first contact 81. A first passivation layer 71 may lie on and encapsulate the bulk color filter 90.

An additional photoelectric conversion region PD′ and a dummy region 111 may each be provided in a corresponding pixel section PX on the optical black area OB. The additional photoelectric conversion region PD′ may be an area doped with impurities (e.g., N-type impurities) of a second conductivity type different from the first conductivity type. The additional photoelectric conversion region PD′ may have a structure similar to that of the photoelectric conversion regions PD in the plurality of pixel sections PX on the pixel array area AR, but may not perform the same operation as that of the photoelectric conversion regions PD. For example, the additional photoelectric conversion region PD′ might not receive light and generate electrical signals. In one example, the additional photoelectric conversion region PD′ assists in removing noise from other photoelectric conversion regions PD. The dummy region 111 may not be doped with impurities.

A second connection structure 60, a second contact 83, and a second passivation layer 73 may be disposed on the pad area PR of the substrate 100. The second connection structure 60 may include a second light-shield pattern 61, a second separation pattern 63, and a second capping pattern 65.

The second light-shield pattern 61 may be disposed on the second surface 100b of the substrate 100. The second light-shield pattern 61 may at least partially cover the passivation layer 312, and may conformally cover an inner wall of each of fifth and sixth trenches TR5 and TR6. The second light-shield pattern 61 may penetrate the photoelectric conversion layer 10 and the upper wiring layer 21. The second light-shield pattern 61 may be connected to the wiring lines in the lower wiring layer 23. Therefore, the second connection structure 60 may electrically connect the photoelectric conversion layer 10 to the wiring layer 20. The second light-shield pattern 61 may include a metallic material (e.g., tungsten). The second light-shield pattern 61 may block light incident onto the pad area PR.

The second contact 83 may fill a remaining portion of the fifth trench TR5. The second contact 83 may include a metallic material (e.g., aluminum). The second contact 83 may serve as an electrical connection path between the image sensor and an external device. The second separation pattern 63 may fill a remaining portion of the sixth trench TR6. The second separation pattern 63 may penetrate the photoelectric conversion layer 10 and a portion of the wiring layer 20. The second separation pattern 63 may include a dielectric material. The second capping pattern 65 may be disposed on the second separation pattern 63. The second passivation layer 73 may cover the second connection structure 60.

A current applied through the second contact 83 may flow toward the deep isolation pattern 150 through the second light-shield pattern 61, the wiring lines in the wiring layer 20, and the first light-shield pattern 51. Electrical signals generated from the photoelectric conversion regions PD in the plurality of pixel sections PX on the pixel array area AR may be externally transferred through the wiring lines in the wiring layer 20, the second light-shield pattern 61, and the second contact 83.

According to some example embodiments of the present inventive concepts, an image sensor may include a gap region to separate color filters from each other and to separate micro-lenses from each other, which may result in increased optical isolation. Accordingly, because optical interference is prevented between pixel sections, crosstalk issues may be prevented, loss of light sensitivity may be minimized, and a signal-to-noise ratio (SNR) may be increased.

Although the present inventive concepts have been described in connection with example embodiments of the present inventive concepts with reference to the accompanying drawings, it will be understood by one of ordinary skill in the art that variations in form and detail may be made therein without departing from the spirit and essential feature of the present inventive concepts. The above disclosed embodiments should thus be considered illustrative and not restrictive.

What is claimed is:

1. An image sensor, comprising:
a substrate that includes a plurality of pixel sections, the substrate having a first surface and a second surface opposite to each other,
an antireflective layer disposed on the second surface of the substrate;
a passivation layer disposed on the antireflective layer;
a plurality of color filters disposed on the passivation layer and corresponding pixel sections;
a plurality of micro-lenses disposed on the color filters; and
a gap region that separates the micro-lenses from each other,
wherein the gap region extends between the color filters and separates the color filters from each other.

2. The image sensor of claim 1, wherein the gap region exposes a portion of a top surface of the passivation layer, and
wherein a thickness of the passivation layer is less than a thickness of the antireflective layer.

3. The image sensor of claim 1, wherein a thickness of the passivation layer is substantially uniform along a direction parallel to the second surface of the substrate.

4. The image sensor of claim 1, further comprising a dielectric layer disposed between the substrate and the antireflective layer,
wherein a thickness of the dielectric layer is less than a thickness of the antireflective layer.

5. The image sensor of claim 1, wherein the gap region has a width in a direction parallel to the second surface of the substrate,
wherein the width of the gap region is about 40 nm to about 350 nm.

6. The image sensor of claim 1, further comprising a deep isolation pattern disposed between the pixel sections and in the substrate,
wherein the gap region vertically overlaps the deep isolation pattern.

7. The image sensor of claim 1, wherein the gap region forms a plurality of regions that has a lattice shape when viewed in plan.

8. The image sensor of claim 1, wherein the gap region exposes sidewalls of the color filters and sidewalls of the micro-lenses.

9. The image sensor of claim 1, further comprising a plurality of grid patterns disposed between the antireflective layer and the passivation layer,
wherein the passivation layer conformally covers top and lateral surfaces of each of the grid patterns.

10. The image sensor of claim 1, further comprising a deep isolation pattern disposed between the pixel sections and in the substrate,
wherein each of the pixel sections includes:
a photoelectric conversion region; and
a doped region that extends along a lateral surface of the deep isolation pattern,
wherein the doped region is disposed between the photoelectric conversion region and the deep isolation pattern.

11. The image sensor of claim 1, further comprising:
a plurality of transistors disposed on the first surface of the substrate; and
a plurality of wiring patterns disposed on the first surface of the substrate and connected to the transistors.

12. An image sensor, comprising:
a substrate that includes a plurality of pixel sections;
an antireflective layer disposed on the substrate;
a plurality of grid patterns disposed between the pixel sections and on the antireflective layer;
a passivation layer disposed on the antireflective layer, the passivation layer conformally covering top and lateral surfaces of the grid patterns;
a plurality of color filters disposed on the passivation layer and corresponding pixel sections;
a plurality of micro-lenses disposed on the color filters; and
a gap region that separates the micro-lenses from each other,
wherein the gap region extends between the color filters and separates the color filters from each other,
wherein the gap region exposes a portion of a top surface of the passivation layer, and
wherein an uppermost surface of the passivation layer is disposed at a level higher than a lowermost surface of each of the color filters.

13. The image sensor of claim 12, wherein a bottom surface of the grid pattern is disposed at a level lower than a bottom surface of each of the color filters.

14. The image sensor of claim 12, wherein
the passivation layer is disposed between a sidewall of the color filter and a sidewall of the grid pattern, and
a thickness of the passivation layer is less than a thickness of the antireflective layer.

15. The image sensor of claim 12, further comprising a deep isolation pattern between the pixel sections and in the substrate,
wherein the grid pattern and the gap region vertically overlap the deep isolation pattern.

16. The image sensor of claim 12, wherein the gap region exposes sidewalls of the color filters and sidewalls of the micro-lenses.

17. The image sensor of claim 12, wherein the gap region forms a plurality of regions that has a lattice shape when viewed in plan.

18. An image sensor, comprising:
a substrate that includes a plurality of pixel sections, the substrate having a first surface and a second surface opposite to each other;
a deep isolation pattern disposed between the pixel sections and in the substrate;
a transistor disposed on the first surface of the substrate;
an antireflective layer disposed on the second surface of the substrate;
a passivation layer disposed on the antireflective layer;
a plurality of color filters disposed on the passivation layer and corresponding pixel sections;
a plurality of micro-lenses disposed on the color filters; and
a gap region that separates the micro-lenses from each other,
wherein a thickness of the passivation layer is less than a thickness of the antireflective layer,
wherein the gap region extends between the color filters and separates the color filters from each other, and
wherein the gap region exposes a portion of a top surface of the passivation layer.

19. The image sensor of claim 18, further comprising a plurality of grid patterns between the antireflective layer and the passivation layer,
wherein the passivation layer conformally covers top and lateral surfaces of the grid patterns.

20. The image sensor of claim 18, wherein each of the pixel sections includes:
a photoelectric conversion region; and
a doped region that extends along a lateral surface of the deep isolation pattern,
wherein the doped region is disposed between the photoelectric conversion region and the deep isolation pattern.
